(19) United States
(12) Patent Application Publication
(10) Pub. No.: US 2026/0182267 A1
(43) Pub. Date: Jun. 25, 2026

(54) METHOD OF DEPOSITING FILM AND APPARATUS FOR DEPOSITING FILM

(71) Applicant: Tokyo Electron Limited, Tokyo (JP)

(72) Inventors: Daichi ITO, Yamanashi (JP); Sung Duk SON, Gyeonggi-do (KR); Jun OGAWA, Yamanashi (JP)

(21) Appl. No.: 19/411,902

(22) Filed: Dec. 8, 2025

(30) Foreign Application Priority Data
Dec. 20, 2024 (JP) 2024-225390

(51) Int. Cl. H10P 14/60; H10P 14/694; H10P 72/00

(52) U.S. Cl. CPC H10P 14/6339; H10P 14/69433; H10P 72/0421

(57) ABSTRACT

A method of depositing a film includes preparing a substrate having a recess on a surface of the substrate, forming a first film along an inner surface of the recess, etching the first film, and further forming the first film along a surface of the first film which has been etched, wherein the etching includes supplying an etching gas including a halogen-containing gas and a gaseous base to the substrate under a plurality of different processing conditions.

### CROSS-REFERENCE TO RELATED APPLICATIONS

The present application is based on and claims priority to Japanese patent application no. 2024-225390 filed on Dec. 20, 2024, with the Japan Patent Office, the entire contents of which are hereby incorporated by reference.

### TECHNICAL FIELD

The disclosures herein relate to methods of depositing films and apparatuses for depositing films.

### BACKGROUND

Patent Literature (PTL) 1 discloses a technology for filling a recess formed in a substrate with a silicon oxide film by alternately repeating a process of silicon oxide film deposition and etching the silicon oxide film using a hydrogen fluoride gas and an ammonia gas.

### CITATION LIST

### Patent Literature

[PTL 1] Japanese Laid-Open Patent Publication no. 2012-199306

### SUMMARY

A method of depositing a film includes preparing a substrate having a recess on a surface of the substrate, forming a first film along an inner surface of the recess, etching the first film, and further forming the first film along a surface of the first film which has been etched, wherein the etching includes supplying an etching gas including a halogen-containing gas and a gaseous base to the substrate under a plurality of different processing conditions.

### BRIEF DESCRIPTION OF THE DRAWINGS

FIG. 1 is a flowchart illustrating a film depositing method according to the present embodiment;

FIG. 2 is a cross-sectional view (1) illustrating the film depositing method according to the present embodiment;

FIG. 3 is a cross-sectional view (2) illustrating the film depositing method according to the present embodiment;

FIG. 4 is a cross-sectional view (3) illustrating the film depositing method according to the present embodiment;

FIG. 5 is a cross-sectional view (4) illustrating the film depositing method according to the present embodiment;

FIG. 6 is a cross-sectional view (5) illustrating the film depositing method according to the present embodiment;

FIG. 7 is a timing chart illustrating a first example of a step S3;

FIG. 8 is a timing chart illustrating a second example of the step S3;

FIG. 9 is a timing chart illustrating a third example of the step S3;

FIG. 10 is a vertical cross-sectional view illustrating the film depositing apparatus according to the present embodiment; and

FIG. 11 is a horizontal cross-sectional view illustrating the film depositing apparatus according to the present embodiment.

### DETAILED DESCRIPTION

In the following, embodiments of the present invention will be described with reference to the accompanying drawings. In the drawings, the same or corresponding constituent elements are denoted with the same reference numerals, and redundant description thereabout may be omitted.

### Film Depositing Method

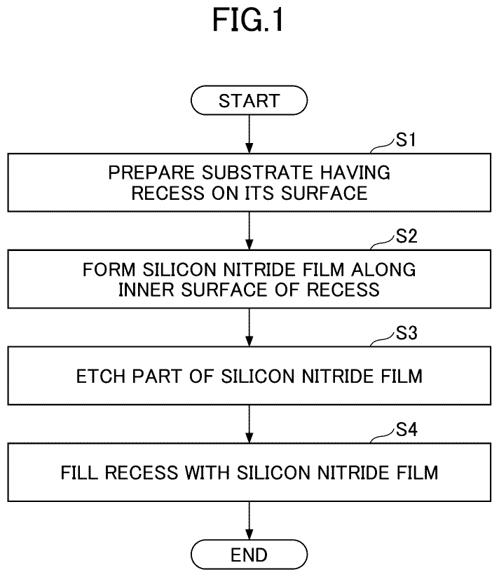

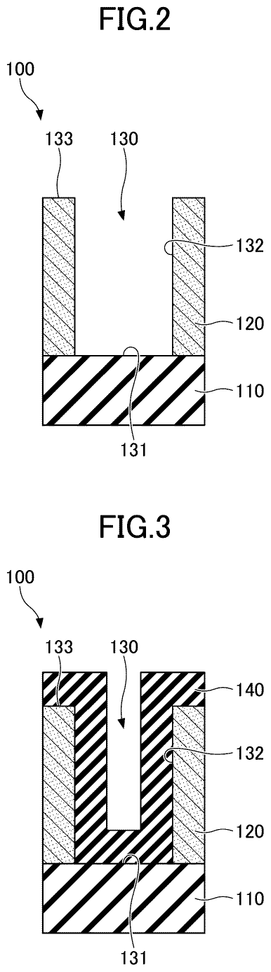

A film depositing method according to the present embodiment will be described with reference to FIGS. 1 to 9. FIG. 1 is a flowchart illustrating the film depositing method according to the present embodiment. FIGS. 2-6 are cross-sectional views illustrating the film depositing method according to the present embodiment. The method of depositing a film according to the present embodiment includes steps S1 to S4 shown in FIG. 1.

In the step S1, as shown in FIG. 2, a substrate 100 is prepared. The substrate 100 has a silicon nitride film 110 and a silicon film 120. The silicon nitride film 110 has a flat top surface. The silicon film 120 is provided on the top surface of the silicon nitride film 110. The silicon film 120 has a projection. The silicon film 120 is, for example, an amorphous silicon film. The silicon nitride film 110 and the silicon film 120 form a recess 130. The recess 130 has a bottom surface 131, a side surface 132, and an upper surface 133. The silicon nitride film 110 forms the bottom surface 131. The silicon film 120 forms the side surface 132 and the upper surface 133. Although the silicon nitride film 110 and the silicon film 120 form the recess 130 in the example of FIG. 2, types of films forming the recess 130 are not limited to these.

In the step S2, as shown in FIG. 3, the silicon nitride film 140 is formed along the inner surface of the recess 130. The silicon nitride film 140 is an example of the first film. The silicon nitride film 140 can be formed, for example, by atomic layer deposition (ALD) in which a dichlorosilane (DCS) gas and an ammonia (NH₃) gas are alternately supplied to the substrate 100. The temperature of the substrate 100 when forming the silicon nitride film 140 is, for example, 630° C. The DCS gas is an example of a silicon-containing gas. An ammonia gas is an example of a nitriding gas.

In the step S3, the silicon nitride film 140 is etched. In the step S3, an etching gas containing a hydrogen fluoride (HF) gas and an ammonia gas is supplied to the substrate 100 under a plurality of different processing conditions. In this case, a filling profile when filling the inside of the recess 130 with the silicon nitride film 140 can be controlled. The hydrogen fluoride gas is an example of a halogen-containing gas. The ammonia gas is an example of a gaseous base.

For example, first, an etching gas containing the hydrogen fluoride gas and the ammonia gas is supplied to the substrate 100 under the first treatment condition. When the etching gas is supplied to the substrate 100, the hydrogen fluoride gas and the ammonia gas contained in the etching gas react with the silicon nitride film 140 to form a modified layer. The modified layer contains, for example, ammonium silicofluoride [(NH₄)₂SiF₆]. The first processing condition is such a condition that, for example, the etching gas does not readily diffuse to a lower portion of the recess 130. In this case, a thicker modified layer is formed above the lower portion of the recess 130. The first processing condition is, for example, as follows.

### <First Processing Condition>

Temperature of the substrate 100: 50° C. or more and 100° C. or less.

Value of pressure inside a processing vessel housing the substrate 100: 10 Pa or more and 13300 Pa or less.

Flow rate of the hydrogen fluoride gas: 10 sccm or more and 5000 sccm or less.

Flow rate of the ammonia gas: 10 sccm or more and 5000 sccm or less.

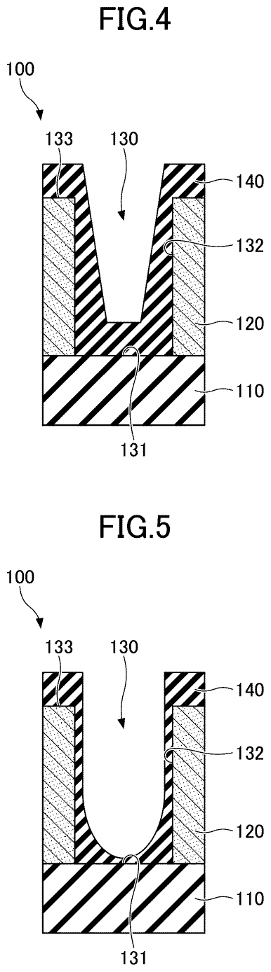

Next, the substrate 100 is heated to a temperature equal to or higher than the temperature at which ammonium silicofluoride is sublimated in an inert gas atmosphere to perform annealing. Thus, ammonium silicofluoride is sublimated, and the modified layer is removed from the substrate 100. As a result, as shown in FIG. 4, the silicon nitride film 140 is etched more in the upper portion than in the lower portion of the recess 130. In other words, the silicon nitride film 140 is etched in a substantially V-shape in a cross-sectional view. The temperature at which ammonium silicofluoride is sublimated is, for example, 200° C.

Next, an etching gas containing a hydrogen fluoride gas and an ammonia gas is supplied to the substrate 100 under the second processing condition. When the etching gas is supplied to the substrate 100, the hydrogen fluoride gas and the ammonia gas contained in the etching gas react with the silicon nitride film 140 to form a modified layer. At this time, since the silicon nitride film 140 is etched in a substantially V-shape, the etching gas tends to be diffused to the lower portion of the recess 130. Therefore, even when the recess 130 has a high aspect ratio, the silicon nitride film 140 formed in the lower portion of the recess 130 can be deteriorated. The second processing condition is, for example, a condition under which the etching gas is more likely to diffuse into the lower portion of the recess 130 than the first processing condition. The second processing condition may be a condition under which at least one of the temperature of the substrate 100, the value of pressure inside the processing vessel which houses the substrate 100, and the supply flow rate of the etching gas is different from the first processing condition. The second processing condition is, for example, as follows.

### <Second Processing Condition>

Temperature of the substrate 100: 50° C. or more and 100° C. or less.

Value of pressure inside the processing vessel housing the substrate 100: 10 Pa or more and 13300 Pa or less.

Flow rate of hydrogen fluoride gas: 10 sccm or more and 5000 sccm or less.

Flow rate of ammonia gas: 10 sccm or more and 5000 sccm or less.

Next, the substrate 100 is heated to a temperature higher than that at which ammonium silicofluoride is sublimated in an inert gas atmosphere to perform annealing. As a result, ammonium silicofluoride is sublimated, and the modified layer is removed from the substrate 100. As a result, as shown in FIG. 5, the silicon nitride film 140 is etched in the upper and lower portions of the recess 130.

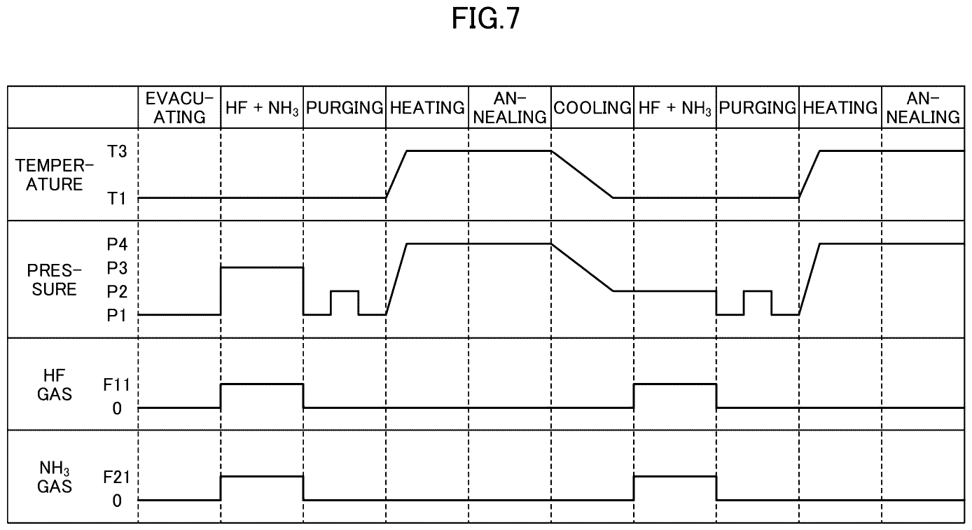

FIG. 7 is a timing chart illustrating a first example of the step S3. In the example shown in FIG. 7, evacuating, supply of etching gas in the first processing condition, purging, heating, annealing, cooling, supply of etching gas in the second processing condition, purging, heating, and annealing are performed in this order. In the second processing condition, the value of pressure inside the processing vessel housing the substrate 100 is lower than that in the first processing condition. Specifically, in the first processing condition, the temperature of the substrate 100 is T1, the value of pressure inside the processing vessel housing the substrate 100 is P3, the flow rate of the hydrogen fluoride gas is F11, and the flow rate of the ammonia gas is F21. In the second processing condition, the temperature of the substrate 100 is T1, the value of pressure inside the processing vessel housing the substrate 100 is P2 (P2<P3), the flow rate of the hydrogen fluoride gas is F11, and the flow rate of the ammonia gas is F21. The lower the value of pressure inside the processing vessel in which the substrate 100 is housed, the more readily the etching gas diffuses to the lower portion of the recess 130. Therefore, by making the value of pressure P2 in the processing vessel in the second processing condition lower than the value of pressure P3 in the processing vessel in the first processing condition, the silicon nitride film 140 can be etched along the inner surface of the recess 130 after the silicon nitride film 140 is etched in a substantially V-shape.

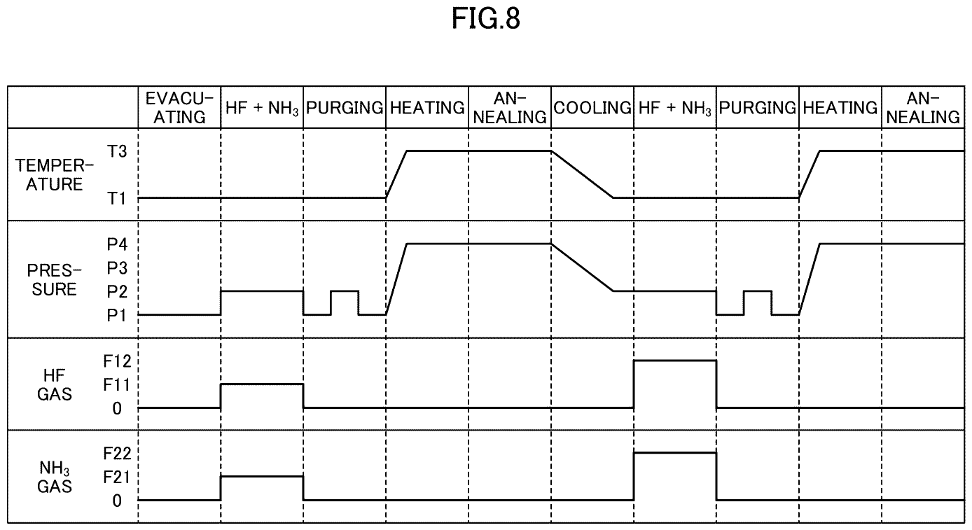

FIG. 8 is a timing chart illustrating a second example of the step S3. In the example shown in FIG. 8, evacuating, supply of the etching gas in the first processing condition, purging, heating, annealing, cooling, supply of the etching gas in the second processing condition, purging, heating, and annealing are performed in this order. In the second processing condition, the flow rate of a fluorine-containing gas and the flow rate of the ammonia gas are greater than those in the first processing condition. Specifically, in the first processing condition, the temperature of the substrate 100 is T1, the value of pressure inside the processing vessel housing the substrate 100 is P2, the flow rate of the hydrogen fluoride gas is F11, and the flow rate of the ammonia gas is F21. In the second processing condition, the temperature of the substrate 100 is T1, the value of pressure inside the processing vessel housing the substrate 100 is P2, the flow rate of the hydrogen fluoride gas is F12 (F12>F11), and the flow rate of the ammonia gas is F22 (F22>F21). The greater the flow rate of the etching gas is, the more readily the etching gas diffuses to the lower portion of the recess 130. Therefore, by making the flow rate of the etching gas in the second processing condition greater than the flow rate of the etching gas in the first processing condition, the silicon nitride film 140 can be etched along the inner surface of the recess 130 after the silicon nitride film 140 is etched in a substantially V-shape.

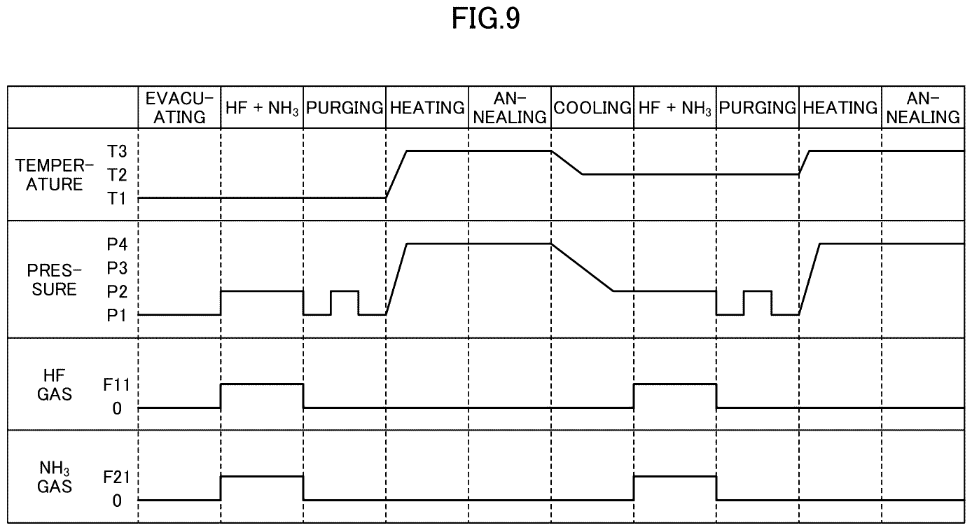

FIG. 9 is a timing chart illustrating a third example of the step S3. In the example shown in FIG. 9, evacuating, supply of etching gas under the first processing condition, purging, heating, annealing, cooling, supply of etching gas under the second processing condition, purging, heating, and annealing are performed in this order. In the second processing condition, the temperature of the substrate 100 is higher than that of the first processing condition. Specifically, in the first processing condition, the temperature of the substrate 100 is T1, the value of pressure inside the processing vessel housing the substrate 100 is P2, the flow rate of the hydrogen fluoride gas is F11, and the flow rate of the ammonia gas is F21. In the second processing condition, the temperature of the substrate 100 is T2 (T2>T1), the value of pressure inside the processing vessel housing the substrate 100 is P2, the flow rate of the hydrogen fluoride gas is F11, and the flow rate of the ammonia gas is F21. The higher the temperature of the substrate 100, the lower the reactivity of the etching gas to the silicon nitride film 140, and the more readily the etching gas diffuses to the lower portion of the recess 130. Therefore, by making the temperature of the substrate 100 in the second processing condition higher than the temperature of the substrate 100 in the first processing condition, the silicon nitride film 140 can be etched along the inner surface of the recess 130 after the silicon nitride film 140 is etched in a substantially V-shape.

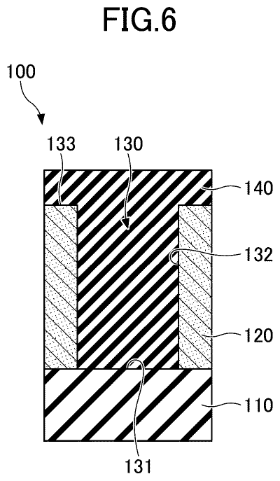

In the step S4, as shown in FIG. 6, the silicon nitride film 140 is further formed along the etched surface of the silicon nitride film 140, and the recess 130 is filled with the silicon nitride film 140. As in the step S2, the silicon nitride film 140 can be formed by atomic layer deposition in which the DCS gas and the ammonia gas are alternately supplied to the substrate 100.

As described above, according to the film depositing method according to the present embodiment, when etching the silicon nitride film 140 in the step S3, etching gas containing hydrogen fluoride gas and ammonia gas is supplied to the substrate 100 under a plurality of different processing conditions. In this case, the filling profile when filling the recess 130 with the silicon nitride film 140 can be controlled.

In the step S3, the value of pressure P2 in the processing vessel under the second processing condition may be lower than the value of pressure P3 in the processing vessel under the first processing condition. In this case, after etching the silicon nitride film 140 in a substantially V-shape, the silicon nitride film 140 can be etched along the inner surface of the recess 130. As a result, the DCS gas and the ammonia gas tend to enter into the lower portion of the recess 130 in the step S4. As a result, occurrence of voids when the recess 130 is filled with the silicon nitride film 140 can be reduced in the step S4, and filling characteristics when the recess 130 is filled with the silicon nitride film 140 can be improved.

In the step S3, the flow rate of the etching gas in the second processing condition may be greater than that in the first processing condition. In this case, after etching the silicon nitride film 140 in a substantially V-shape, the silicon nitride film 140 can be etched along the inner surface of the recess 130. As a result, the DCS gas and the ammonia gas tend to enter into the lower portion of the recess 130 in the step S4. As a result, occurrence of voids when the recess 130 is filled with the silicon nitride film 140 can be reduced in the step S4, and filling characteristics when the recess 130 is filled with the silicon nitride film 140 can be improved.

In the step S3, the temperature of the substrate 100 in the second processing condition may be set higher than the temperature of the substrate 100 in the first processing condition. In this case, after etching the silicon nitride film 140 in a substantially V-shape, the silicon nitride film 140 can be etched along the inner surface of the recess 130. As a result, the DCS gas and the ammonia gas tend to enter into the lower portion of the recess 130 in the step S4. As a result, occurrence of voids when the recess 130 is filled with the silicon nitride film 140 can be reduced in the step S4, and filling characteristics when the recess 130 is filled with the silicon nitride film 140 can be improved.

In the example shown in FIG. 1, the case where the recess 130 is filled with the silicon nitride film 140 by performing the steps S1, S2, S3, and S4 one by one in this order has been described, but the present disclosure is not limited to this. For example, after performing the steps S1 and S2, the recess 130 may be filled with the silicon nitride film 140 by alternately repeating the steps S3 and S4.

### Film Depositing Apparatus

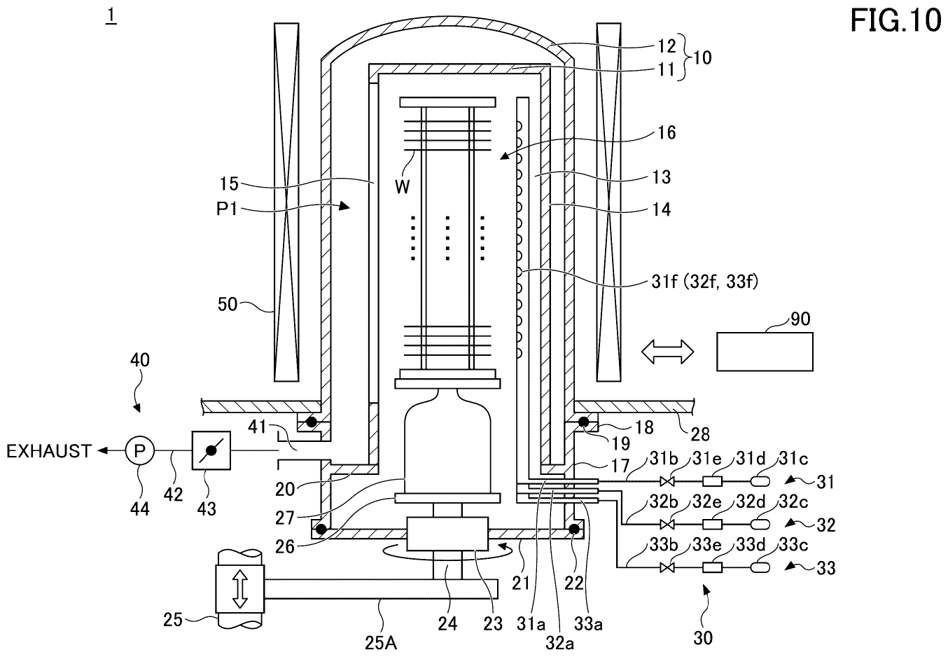

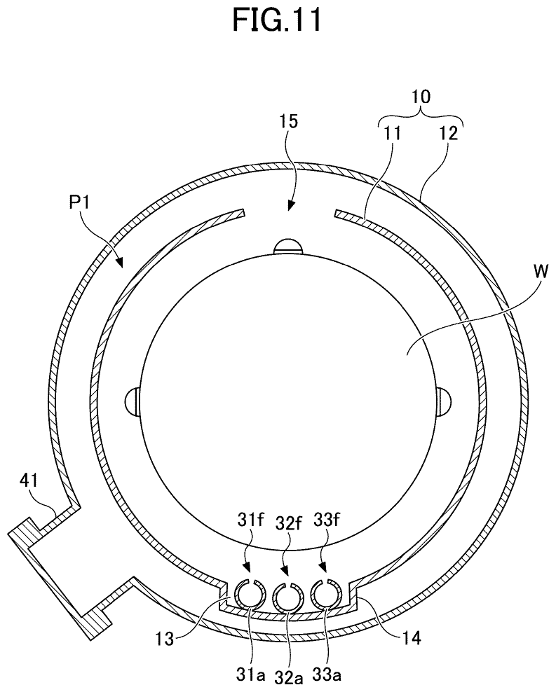

A film depositing apparatus 1 according to the present embodiment will be described with reference to FIGS. 10 and 11. FIG. 10 is a vertical cross-sectional view illustrating the film depositing apparatus 1 according to the present embodiment. FIG. 11 is a horizontal cross-sectional view illustrating the film depositing apparatus 1 according to the present embodiment.

The film depositing apparatus 1 is a batch-type apparatus which processes a plurality of substrates W at a time. The substrates W are, for example, semiconductor wafers. The film depositing apparatus 1 includes a processing vessel 10, a gas supply 30, an exhaust 40, a heater 50, and a controller 90.

The inside of the processing vessel 10 can be depressurized. The processing vessel 10 houses the substrates W. The processing vessel 10 has an inner tube 11 and an outer tube 12. The inner tube 11 has a tubular shape with a ceiling whose lower end is open. The outer tube 12 has a tubular shape with a ceiling whose lower end is open to cover the outside of the inner tube 11. The inner tube 11 and the outer tube 12 are formed of a heat-resistant material such as quartz. The inner tube 11 and the outer tube 12 have a double tube structure coaxially arranged.

A housing 13 for housing a gas supply tube is formed on a lateral wall of the inner tube 11 along the longitudinal direction (top-bottom direction). For example, a part of the lateral wall of the inner tube 11 is projected outward to form a projection 14, and the inside of the projection 14 is formed as the housing 13.

A rectangular opening 15 is formed in the lateral wall of the inner tube 11 along the longitudinal direction. The opening 15 faces the housing 13.

The opening 15 is a gas exhaust port formed to exhaust gas in the inner tube 11. The length of the opening 15 is equal to the length of a boat 16 or longer than the length of the boat 16 so as to extend in the top-bottom direction.

The lower end of the processing vessel 10 is supported by a tubular manifold 17. The manifold 17 is formed of, for example, stainless steel. A flange 18 is formed at the upper end of the manifold 17. The flange 18 supports the lower end of the outer tube 12. A seal member 19 such as an O-ring is provided between the flange 18 and the lower end of the outer tube 12. Thus, the inside of the outer tube 12 is hermetically maintained.

An annular support 20 is provided on the inner wall of the upper portion of the manifold 17. The support 20 supports the lower end of the inner tube 11. A lid 21 is hermetically attached to the opening of the lower end of the manifold 17 through a seal member 22 such as an O-ring. Thus, the opening of the lower end of the processing vessel 10, that is, the opening of the manifold 17 is hermetically closed. The lid 21 is formed of, for example, stainless steel.

A rotating shaft 24 penetrates through the center of the lid 21 through a magnetic fluid seal 23. The lower portion of the rotating shaft 24 is rotatably supported by an arm 25A of an elevating mechanism 25 including a boat elevator.

A rotating plate 26 is provided at the upper end of the rotating shaft 24. On the rotating plate 26, a boat 16 for holding the substrates W through a quartz heat insulation table 27 is placed. The boat 16 rotates by rotating the rotating shaft 24. The boat 16 moves up and down integrally with the lid 21 by elevating and lowering the elevating mechanism 25. Thus, the boat 16 is inserted into and removed from the processing vessel 10. The boat 16 can be housed in the processing vessel 10. The boat 16 holds the plurality (e.g., 50 to 150) of substrates W in a shelf shape. The boat 16 holds the plurality of substrates W substantially horizontally at intervals in the vertical direction.

The gas supply 30 is configured to introduce various processing gases into the inner tube 11. The gas supply 30 includes a DCS gas supply 31, an ammonia gas supply 32, and a hydrogen fluoride gas supply 33.

The DCS gas supply 31 includes a gas supply tube 31a in the processing vessel 10, and a supply channel 31b outside the processing vessel 10. The supply channel 31b is provided with a DCS gas source 31c, a mass flow controller 31d, and a valve 31e in order from the upstream to the downstream in the gas flow direction. Thus, the supply timing of the DCS gas from the DCS gas source 31c is controlled by the valve 31e, and the flow rate is adjusted to a predetermined flow rate by the mass flow controller 31d. The DCS gas flows into the gas supply tube 31a from the supply channel 31b and is discharged into the processing vessel 10 from the gas supply tube 31a.

The ammonia gas supply 32 is provided with a gas supply tube 32a in the processing vessel 10 and a supply channel 32b outside the processing vessel 10. The supply channel 32b is provided with an ammonia gas source 32c, a mass flow controller 32d, and a valve 32e in order from the upstream to the downstream in the gas flow direction. Thus, the supply timing of the ammonia gas of the ammonia gas source 32c is controlled by the valve 32e, and the flow rate of the ammonia gas is adjusted to a predetermined flow rate by the mass flow controller 32d. The ammonia gas flows into the gas supply tube 32a from the supply channel 32b and is discharged from the gas supply tube 32a into the processing vessel 10.

The hydrogen fluoride gas supply 33 includes a gas supply tube 33a in the processing vessel 10, and a supply channel 33b outside the processing vessel 10. The supply channel 33b is provided with the hydrogen fluoride gas source 33c, the mass flow controller 33d, and the valve 33e in order from the upstream to the downstream in the gas flow direction. Thus, the supply timing of the hydrogen fluoride gas from the hydrogen fluoride gas source 33c is controlled by the valve 33e, and the flow rate is adjusted to a predetermined level by the mass flow controller 33d. The hydrogen fluoride gas flows into the gas supply tube 33a from the supply channel 33b and is discharged into the processing vessel 10 from the gas supply tube 33a.

The gas supply tubes 31a, 32a, and 33a are fixed to the manifold 17. The gas supply tubes 31 a, 32 a, and 33a are formed of, for example, quartz. Each of the gas supply tubes 31a, 32a, and 33a extends linearly along the vertical direction in proximity of the inner tube 11, bend in an L-shape in the manifold 17 and extend in the horizontal direction, which penetrates the manifold 17. The gas supply tubes 31a, 32a, and 33a are disposed along the circumferential direction of the inner tube 11 and are formed at the same height.

A plurality of discharge ports 31f, 32f, and 33f are provided at respective portions of the gas supply tubes 31a, 32a, and 33a located in the inner tube 11. The discharge ports 31f, 32f, and 33f are formed at predetermined intervals along the extending direction of the gas supply tubes 31a, 32a, and 33a. The discharge ports 31f, 32f, and 33f discharge gas horizontally toward the substrates W from the outside in the radial direction of the substrates W. Each of the discharge ports 31f, 32f, and 33f discharges the gas in parallel to main surfaces of the substrates W. The distance between the discharge ports is set equal to, for example, the distance between the substrates W held by the boat 16. The position of each of the discharge ports in a height direction is set at, for example, an intermediate position between the substrates W adjacent in the top-bottom direction. In this case, the discharge ports can efficiently supply gas to opposing surfaces between adjacent substrates W.

The gas supply 30 may mix a plurality of types of gas and discharge the mixed gas from one gas supply tube. The gas supply tubes 31a, 32a, and 33a may have shapes and arrangements different from each other. The gas supply 30 may further include a gas supply tube for supplying another gas, for example, an inert gas.

The exhaust 40 exhausts the gas exhausted from the inner tube 11 through the opening 15 and exhausted from the gas outlet 41 through a space P1 between the inner tube 11 and the outer tube 12. The gas outlet 41 is an upper lateral wall of the manifold 17 and is formed above the support 20. An exhaust passage 42 is connected to the gas outlet 41. A pressure regulating valve 43 and a vacuum pump 44 are sequentially interposed in the exhaust passage 42 to exhaust the inside of the processing vessel 10.

The heater 50 is provided around the outer tube 12. The heater 50 is provided, for example, on the base plate 28. The heater 50 has a cylindrical shape so as to cover the outer tube 12. The heater 50 includes, for example, a heating element and heats each of the substrates W in the processing vessel 10.

The controller 90 is an electronic circuit such as a CPU (Central Processing Unit), an FPGA (Field Programmable Gate Array), and an ASIC (Application Specific Integrated Circuit). The controller 90 executes various control operations described herein by executing instruction codes stored in a memory or by designing a circuit for a special application.

### Operation of Apparatus for Depositing Film

The operation of the film depositing apparatus 1 when the steps S2 to S4 of the film depositing method according to the present embodiment are performed in the film depositing apparatus 1 will be described. The operation of the film depositing apparatus 1 described below is performed controlled by the controller 90.

First, the elevating mechanism 25 carries the boat 16 holding the plurality of substrates W into the processing vessel 10, and the lid 21 hermetically closes the opening of the lower end of the processing vessel 10. Subsequently, the exhaust 40 depressurizes the inside of the processing vessel 10, and the heater 50 adjusts the temperature of the substrates W to a predetermined temperature. The substrates W may be the substrates 100 described above.

Next, the controller 90 controls the gas supply 30, the exhaust 40, and the heater 50 so as to execute the steps S2 to S4.

Next, after raising the value of pressure inside the processing vessel 10 to the value of atmospheric pressure and lowering the temperature in the processing vessel 10 to an unloading temperature, the controller 90 controls the elevating mechanism 25 to unload the boat 16 from the processing vessel 10.

In the above example, the steps S2 to S4 are performed in the same film depositing apparatus 1, but at least one of the steps S2, S3, and S4 may be performed in an apparatus different from the film depositing apparatus 1.

Further, the present invention is not limited to these embodiments, and various variations and modifications may be made without departing from the scope of the present invention.

In the above embodiments, the case where the silicon-containing gas is a DCS gas has been described, but the present disclosure is not limited to this. The silicon-containing gas may be a fluorine-containing silicon gas such as SiF₄, SiHF₃, SiH₂F₂, or SiH₃F, a chlorine-containing silicon gas such as SiCl₄, SiHCl₃, SiH₂Cl₂ (DCS), SiH₃Cl, or Si₂Cl₆, a bromine-containing silicon gas such as SiBr₄, SiHBr₃, SiH₂Br₂, or SiH₃Br, or a combination of these.

In the above embodiments, the case where the nitriding gas is an ammonia gas has been described, but the present disclosure is not limited to this. The nitriding gas may be an ammonia gas, a diazene (N₂H₂) gas, a hydrazine (N₂H₄) gas, a monomethylhydrazine (CH₃(NH)NH₂) gas, or a combination of these.

In the above embodiments, the case where the halogen-containing gas is a hydrogen fluoride gas has been described, but the present disclosure is not limited to this. The halogen-containing gas may be a fluorine (F₂) gas, a chlorine trifluoride (ClF₃) gas, or a nitrogen trifluoride (NF₃) gas.

In the above embodiments, the case where the gaseous base is ammonia gas has been described, but the present disclosure is not limited to this. The gaseous base may be dimethylamine, trimethylamine, or hydrazine.

In the above embodiment, the case where the first film is a silicon nitride film 140 has been described, but the present disclosure is not limited to this. The first film may be a silicon oxide film, a SiON film, a SiOCN film, a SiBN film, or a SiOC film.

In the above embodiment, the case where the film depositing apparatus is a batch type apparatus for processing a plurality of substrates at one time has been described, but the present disclosure is not limited to this. For example, the apparatus for depositing a film may be a single-wafer type apparatus for processing substrates one by one. For example, the apparatus for depositing a film may be a semi-batch type apparatus for processing substrates by rotating a rotary table on which a plurality of substrates are mounted, revolving each substrate, and repeatedly passing through a processing gas supply region arranged along the radial direction of the rotary table.

According to the present disclosure, it is possible to control the filling profile when filling the recess with a film.

1. A method of depositing a film, comprising:
preparing a substrate having a recess on a surface of the substrate;
forming a first film along an inner surface of the recess;
etching the first film; and
further forming the first film along a surface of the first film which has been etched,
wherein the etching includes supplying an etching gas including a halogen-containing gas and a gaseous base to the substrate under a plurality of different processing conditions.

2. The method of depositing the film according to claim 1, wherein:
the etching includes:
supplying the substrate with the etching gas under a first processing condition; and
supplying the substrate with the etching gas under a second processing condition, which is different from the first processing condition; and
the second processing condition is different from the first processing condition in at least one of a temperature of the substrate, a value of pressure inside a processing vessel which houses the substrate, or a supply flow rate of the etching gas.

3. The method of depositing the film according to claim 2, wherein the value of pressure inside the processing vessel which houses the substrate is lower in the second processing condition than in the first processing condition.

4. The method of depositing the film according to claim 2, wherein the supply flow rate is greater in the second processing condition than in the first processing condition.

5. The method of depositing the film according to claim 2, wherein the temperature of the substrate is higher in the second processing condition than in the first processing condition.

6. The method of depositing the film according to claim 2, wherein the etching includes annealing the substrate at a temperature higher than a temperature of the first processing condition and a temperature of the second processing condition.

7. The method of depositing the film according to claim 1, wherein the etching and the further forming of the first film are alternately repeated.

8. The method of depositing the film according to claim 1, wherein the etching gas is supplied from an outer position in a radial direction of the substrate in parallel to a main surface of the substrate.

9. The method of depositing the film according to claim 1, wherein the first film is a silicon nitride film.

10. The method of depositing the film according to claim 1, wherein the halogen-containing gas is a hydrogen fluoride gas, and the gaseous base is an ammonia gas.

11. An apparatus for depositing a film, comprising:
a processing vessel configured to house a substrate;
a gas supply configured to supply a gas to an inside of the processing vessel; and
a controller, wherein:
the controller is configured to execute:
preparing the substrate having a recess on a surface of the substrate;
forming a first film along an inner surface of the recess;
etching the first film; and
further forming the first film along a surface of the first film which has been etched; and
the etching includes supplying an etching gas including a halogen-containing gas and a gaseous base to the substrate under a plurality of different processing conditions.
